(19) United States
(12) Patent Application Publication
(10) Pub. No.: US 2006/0045669 A1
(43) Pub. Date: Mar. 2, 2006

(54) Clean room, local cleaning system, methods of use thereof, and clean room monitoring system

(75) Inventors: Yoshiaki Namioka, Toyama (JP); Norishige Aoki, Kyoto (JP); Tsuyoshi Miyata, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/151,543

(22) Filed: Jun. 14, 2005

(30) Foreign Application Priority Data
Jun. 16, 2004 (JP) 2004-178032

(51) Int. Cl. H01L 21/677

(52) U.S. Cl. 414/217.1

(57) ABSTRACT

A local cleaning system comprises a plurality of transport rails arranged below a ceiling of a clean room to form a grid, and a self-traveling fan filter unit that can be moved along the transport rails. The self-traveling fan filter unit is moved to a predetermined region of the clean room using the transport rails, thereby forming a locally cleaned region having a higher cleanliness level than a region of the clean room excluding the predetermined region.

### CROSS-REFERENCE TO RELATED APPLICATIONS

The disclosure of Japanese Patent Application No. 2004-178032 filed on Jun. 16, 2004 including specification, drawings and claims is incorporated herein by reference in its entirety.

### BACKGROUND OF THE INVENTION

(1) Field of the Invention

The present invention relates to a clean room, a local cleaning system, methods of use thereof, and a clean room monitoring system in a semiconductor device fabrication plant.

(2) Description of Related Art

As the processing precision of semiconductor devices becomes finer, there has been a growing demand for a higher cleanliness level of a process environment. This has increased the adoption of a local cleaning (mini-environment) system that permits the control of the cleanliness level at low cost and with excellent controllability.

In the mini-environment system, the following clean room is typically used: The inside of the mini environment, which is a local region of the clean room in which a semiconductor substrate is exposed to an atmosphere, is set to have a cleanliness level of Class 1 (one or less 0.1-μm-or-more-diameter foreign particle per 0.028 m³ (one cubic foot)). The other region of the clean room is set to have a cleanliness level of approximately Class 1000 (1000 or less 0.1-μm-or-more-diameter foreign particles per one cubic foot).

However, during facility maintenance or when troubles are coped with, the inside of the mini environment or the inside of a process chamber is exposed to a low-cleanliness-level atmosphere to which a semiconductor substrate is not intended to be exposed. Therefore, the inside of the mini environment or the like might be contaminated. Furthermore, the ambient environment might be contaminated by particles or the like produced during operations for the facility maintenance.

The following method is known as a method for preventing these problems. A simple mobile local clean booth is composed of columns, fan filter units and a vinyl curtain in a clean room so that an arbitrary region of the clean room has a high cleanliness level (see Japanese Unexamined Patent Publication No. 4-347435).

However, this method in which the local clean booth is constructed is not suitable for use in daily facility maintenance. The reason for this is that this method requires a lot of labor and a long time to transport the structural components of the local clean booth to that site and construct the local clean booth. Furthermore, it is very difficult to place the local clean booth requiring the columns in the clean room, because semiconductor device fabrication facilities are packed as densely as possible for the purpose of efficiently utilizing the area of the clean room. In addition, during the construction of the local clean booth, the ambient environment is contaminated.

### SUMMARY OF THE INVENTION

The present invention is made to solve the above conventional problems, and its object is to realize a local cleaning system that permits a simple construction of a locally cleaned region having a necessary cleanliness level in a necessary area of the clean room in a short time, methods of use thereof, and a clean room monitoring system.

In order to achieve the above object, in the local cleaning system of the present invention, a locally cleaned region is formed in the clean room by a fan filter unit automatically traveling along rails for transporting the fan filter unit (hereinafter, referred to as “transport rails”), which are located in the clean room.

To be specific, a clean room of the present invention in which a fabrication facility for semiconductor devices is placed comprises a plurality of transport rails arranged below a ceiling of the clean room to form a grid.

According to the clean room of the present invention, the transport rails are arranged below the ceiling to form a grid. Therefore, materials, parts, equipment, and the like can be transferred to an arbitrary site in the clean room without the need for any labor. This can prevent the clean room from being contaminated due to the movement of human beings. Since the fan filter unit is moved using the transport rails, a high-cleanliness-level region can locally be formed in the clean room. This makes it possible to both save labor and enhance the cleanliness level, resulting in the realized clean room suitable for the fabrication of semiconductor devices.

A local cleaning system of the present invention comprises a plurality of transport rails arranged below a ceiling of a clean room to form a grid, and a self-traveling fan filter unit that can be moved along the transport rails, wherein the self-traveling fan filter unit is moved to a predetermined region of the clean room using the transport rails, thereby forming a locally cleaned region having a higher cleanliness level than a region of the clean room excluding the predetermined region.

The local cleaning system of the present invention comprises the self-traveling fan filter unit that can be carried along the transport rails arranged in the clean room to form a grid. Therefore, the locally cleaned region of a predetermined size can simply be formed in a predetermined region of the clean room in a short time by merely moving the fan filter unit. This makes it possible to immediately cope with the facility maintenance and the occurrence of an abnormal condition, resulting in the improved productivity of the facility.

Furthermore, unlike the local clean booth, it is not necessary to keep regions of the clean room in which columns are to be placed. This makes it possible to effectively utilize space in the clean room. Moreover, the local cleaning system of the present invention eliminates the need for assembly operations. This can achieve labor savings and prevent the clean room from being contaminated due to the assembly operations.

In the local cleaning system of the present invention, the self-traveling fan filter unit preferably has at least one of a filter for particle removal and a chemical filter. With this structure, an environment with a necessary cleanliness level can be constructed with reliability.

The local cleaning system of the present invention may further comprise a plurality of self-traveling partition units that can be moved along the transport rails and form a partition for blocking the flow of air, wherein the self-traveling partition units are preferably placed around the locally cleaned region, thereby blocking the flow of air between the locally cleaned region and the region of the clean room excluding the predetermined region. This structure can certainly prevent the cleanliness level of the locally cleaned region from decreasing due to the air flow from the region of the clean room excluding the locally cleaned region into the locally cleaned region.

In this case, each said self-traveling partition unit is preferably an air curtain unit for blowing air out to form an air curtain. Alternatively, each said self-traveling partition unit may be a roll curtain unit in which a roll curtain can be contained. This structure can certainly isolate the locally cleaned region from the other region of the clean room.

In the local cleaning system of the present invention, an area in which the self-traveling fan filter unit and the self-traveling partition units are contained is preferably formed outside the clean room. In this way, space in the clean room can effectively be utilized.

In a method of use of a local cleaning system according to a first aspect of the present invention including a clean room in which a fabrication facility for semiconductor devices is placed, the clean room comprising transport rails arranged below a ceiling of the clean room to form a grid and a self-traveling fan filter unit that can be moved along the transport rails, the self-traveling fan filter unit being moved to a predetermined region of the clean room using the transport rails and thereby forming a locally cleaned region in the predetermined region of the clean room to have a higher cleanliness level than a region thereof excluding the predetermined region thereof, said method comprises the steps of: forming a locally cleaned region in a region of the clean room in which the fabrication facility for semiconductor devices is placed; and performing maintenance of the fabrication facility for semiconductor devices in the locally cleaned region.

The method of use of a local cleaning system according to the first aspect of the present invention allows the vicinity of the semiconductor device fabrication facility being subjected to maintenance to simply and promptly reach a predetermined cleanliness level. This can sharply reduce the number of man-hours required for maintenance and prevent the semiconductor device fabrication facility from being contaminated during the maintenance.

It is preferable that the method according to the first aspect of the present invention further comprises the step of transferring parts, tools or equipment used in the step of performing maintenance of the facility to the locally cleaned region using the transport rails. This facilitates the transportation of materials for maintenance and can prevent an environment from being contaminated.

In a method of use of a local cleaning system according to a second aspect of the present invention including a clean room in which a fabrication facility for semiconductor devices is placed, the clean room comprising transport rails arranged below a ceiling of the clean room to form a grid and a self-traveling fan filter unit that can be moved along the transport rails, the self-traveling fan filter unit being moved to a predetermined region of the clean room using the transport rails and thereby forming a locally cleaned region in the predetermined region of the clean room to have a higher cleanliness level than a region thereof excluding the predetermined region, said method comprises the steps of: forming a locally cleaned region in a region of the clean room located in the vicinity of a carry-in/out port and a region thereof serving as a carry-in/out path; and carrying the fabrication facility for semiconductor devices into and out of the clean room along the carry-in/out path contained in the locally cleaned region.

The method of use of a local cleaning system according to the second aspect of the present invention makes it possible to locally clean, with extreme ease, the carry-in/out port and path for the facility. Therefore, the facility can be carried into and out of the clean room with the ambient environment clean. Furthermore, the method of use of the local cleaning system permits the blocking of the air flow between the region including the carry-in/out port and path and the other region of the clean room. This can prevent the clean room from being contaminated when the facility is carried into and out of the clean room.

In a method of use of a local cleaning system according to a third aspect of the present invention including a clean room in which a fabrication facility for semiconductor devices is placed, the clean room comprising transport rails arranged below a ceiling of the clean room to form a grid and a self-traveling fan filter unit that can be moved along the transport rails, the self-traveling fan filter unit being moved to a predetermined region of the clean room using the transport rails and thereby forming a locally cleaned region in the predetermined region of the clean room to have a higher cleanliness level than a region thereof excluding the predetermined region, said method comprises the steps of: forming the locally cleaned region in a region of the clean room in which the semiconductor devices are to be fabricated; and fabricating the semiconductor devices in the locally cleaned region.

In the method of use of a local cleaning system according to the third aspect of the present invention, a region of the clean room in which a semiconductor substrate is exposed can locally be cleaned using the local cleaning system of the present invention. This can prevent the semiconductor substrate from being contaminated due to the atmosphere in the region of the clean room in which the semiconductor substrate is exposed. Furthermore, the whole clean room need not be cleaned to a high degree. This makes it possible to save power of the semiconductor device fabrication facility.

A clean room monitoring system of the present invention comprises: a plurality of transport rails arranged below a ceiling of a clean room to form a grid; a self-traveling monitoring unit to which a gas detector or a viewing camera apparatus is mounted and which can be moved along the transport rails; and a self-traveling-monitoring-unit controller located outside the clean room to move and monitor the self-traveling monitoring unit.

The clean room monitoring system of the present invention can easily move the monitoring unit to an arbitrary site in the clean room. Therefore, the state of the clean room can accurately be monitored by the monitoring unit.

### BRIEF DESCRIPTION OF THE DRAWINGS

FIG. 1 is a cross-sectional view schematically showing the structure of a clean room having a local cleaning system according to a first embodiment of the present invention.

FIG. 2 is a plan view showing the configuration of the clean room having the local cleaning system according to the first embodiment of the present invention.

FIG. 3 is a plan view showing the configuration of a clean room having a local cleaning system according to a second embodiment of the present invention.

FIG. 4 is a cross-sectional view schematically showing the structure of a clean room having a clean room monitoring system according to a third embodiment of the present invention.

### DETAILED DESCRIPTION OF THE INVENTION

### Embodiment 1

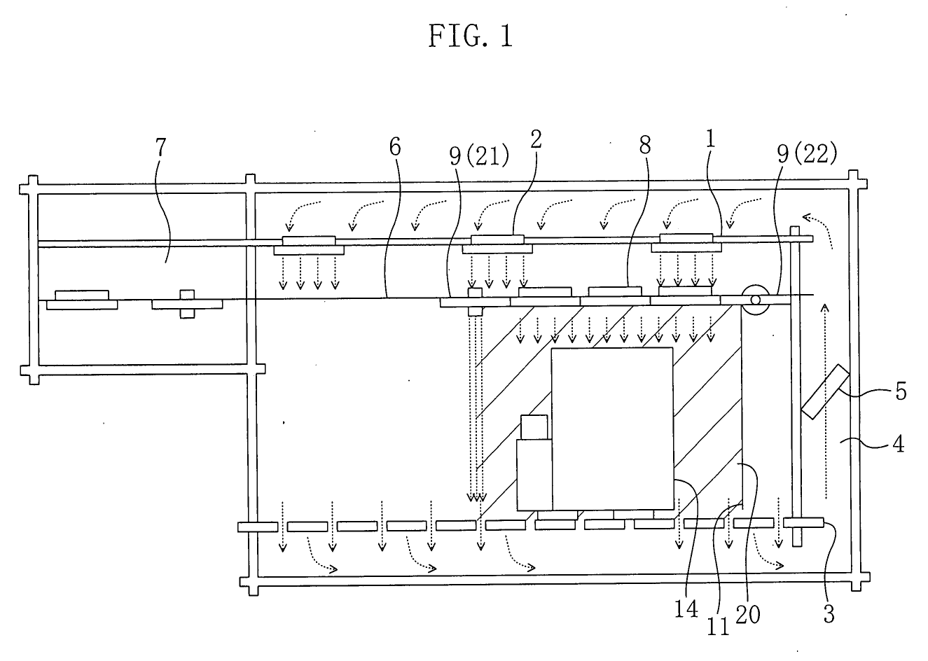

A first embodiment of the present invention will be described with reference to the drawings. FIG. 1 shows a cross-sectional structure of a clean room having a local cleaning system according to the present invention. As shown in FIG. 1, a system ceiling of the clean room is provided with fixed fan filter units 2 each comprising a filter and a fan, and clean air is supplied from the fixed fan filter units 2 toward a free access floor 3 by downflow (laminar flow). The free access floor 3 constitutes a grating, and thus the clean air supplied from the fan filter units 2 passes through the grating and reaches under the free access floor 3. The clean air that has reached under the free access floor 3 is recovered by a return duct 4 positioned between the inner wall and outer wall of the clean room and then conditioned by a dry coil unit 5 mounted in the return duct 4. Thereafter, the conditioned clean air is again supplied to the fan filter units 2 and circulates in the clean room. With this structure, the environment in the clean room is kept at Class 1000 (1000 or less 0.1-μm-or-more-diameter foreign particles per one cubic foot).

Transport rails 6 are placed between the system ceiling 1 and the free access floor 3 while being suspended from the system ceiling 1. Self-traveling fan filter units 8 serving as traveling objects into each of which a filter and a fan are incorporated can travel by itself along the transport rails 6. The transport rails 6 are arranged over the whole area of the clean room to form a grid and can move the traveling objects along the transport rails 6 and toward an arbitrary site in the clean room. Furthermore, some of the transport rails 6 are extended to an external storage area 7 located outside the clean room. Thus, unused one or ones of the traveling objects can be stored in the external storage area 7. Commonly used transport rails of an arbitrary type can be used as the transport rails 6. For example, a transport rail on which traveling objects travel or a transport rail from which traveling objects are suspended can be used thereas.

The self-traveling fan filter units 8 are designed in accordance with the size of each of grid squares or rectangles formed by the transport rails 6. Therefore, the plurality of self-traveling fan filter units 8 can be arbitrarily arranged along the grid squares or rectangles. Thus, a necessary number of self-traveling fan filter units 8 are moved to a necessary site, thereby forming a locally cleaned region 20 in an arbitrary region of the clean room. Furthermore, unused one or ones of the self-traveling fan filter units 8 can be moved to the external storage area 7 located outside the clean room and stored therein.

A HEPA filter or an ULPA filter serving as a filter for particle removal need be used for a filter of each self-traveling fan filter unit 8 in accordance with the cleanliness level of the formed locally cleaned region 20. A chemical filter for removing chemicals may be used alone or in combination with the filter for particle removal as necessary.

Furthermore, the fans of the self-traveling fan filter units 8 are allowed to operate and stop for each unit and can be adjusted for each unit to obtain an appropriate volume of air. This makes the flow of air in the locally cleaned region 20 uniform, resulting in a higher-level cleanliness. Furthermore, power saving can be achieved by stopping an unnecessary unit or units.

Moreover, self-traveling partition units 9 are arranged around the locally cleaned region 20, thereby blocking the flow of air between the locally cleaned region 20 and the other region of the clean room. This can prevent the inside of the locally cleaned region 20 from being contaminated from outside and prevent, also when contaminants are produced during the facility maintenance in the locally cleaned region 20, the contaminants from dispersing outward.

For example, air curtain units 21, roll curtain units 22 or the like can be used as the self-traveling partition units 9. The air curtain units 21 are each obtained by mounting, to each traveling object, a fan for blowing clean air toward the free access floor 3 in an arbitrary volume of air and can adjust the volume of air in each unit.

The roll curtain units 22 are units of traveling objects in which curtains of antistatic sheets made of vinyl chloride, polyethylene terephthalate or fluoroplastics can be contained. The curtains are pulled out in units and can be extended toward the free access floor 3 to reach an arbitrary site. The lower end 11 of each curtain can be fixed to the free access floor 3.

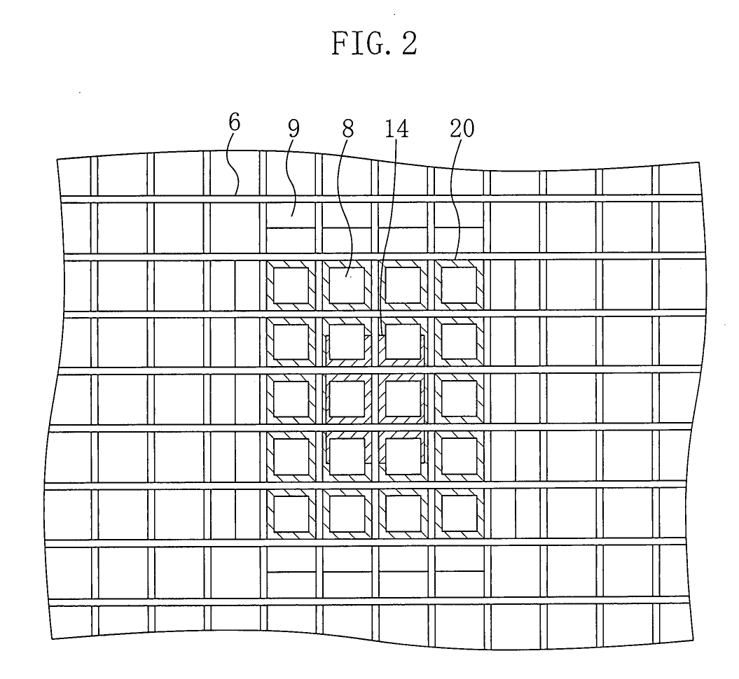

Next, methods of use of the local cleaning system according to this embodiment will be described. FIG. 2 shows a plan configuration of a locally cleaned region 20 formed below self-traveling fan filter units 8 and isolated from the other region of the clean room by self-traveling partition units 9.

As shown in FIG. 2, twenty self-traveling fan filter units 8 are mounted to grid squares or rectangles, respectively, formed by transport rails 6 and located over a region in which a fabrication facility 14 for semiconductor devices is placed. A locally cleaned region 20 is formed in regions of the clean room overlapping with the fabrication facility 14 and located therearound.

An ULPA filter is used as a filter of each self-traveling fan filter unit 8. The inside of the locally cleaned region 20 is set to have a cleanliness level of Class 1 (one or less 0.1-μm-or-more-diameter particle per one cubic foot). This can prevent the inside of a chamber of the fabrication facility 14 from being contaminated due to an atmosphere in the chamber, for example, also during the maintenance of the chamber.

Eighteen self-traveling partition units 9 are arranged to surround the locally cleaned region 20. The locally cleaned region 20 is isolated from the other region of the clean room. This can prevent contaminants from entering from outside into the locally cleaned region 20 and contaminants produced during maintenance operations from dispersing outward.

Although in this embodiment a description was given of the case where the semiconductor device fabrication facility 14 is completely contained in the locally cleaned region 20, a region covering only a part of the semiconductor device fabrication facility 14 to be subjected to maintenance may be locally cleaned as necessary.

The inside of the locally cleaned region 20 need be set to have a necessary cleanliness level in accordance with operations carried out inside the locally cleaned region 20. The cleanliness level can be controlled by the number of the self-traveling fan filter units 8 located in the locally cleaned region 20, the type of the filter of each self-traveling fan filter unit 8, the flow rate of clean air to be supplied to the locally cleaned region 20, and other factors. Only the partition units 9 for preventing contaminants from dispersing outward may be mounted on the transport rails 6 without mounting any self-traveling fan filter unit 8 thereon.

Furthermore, parts, jigs, tools, or materials used for maintenance are carried on a general-purpose transport unit using the transport rails 6. This can reduce the movement of human beings in the clean room to a minimum. This makes it possible to further reduce contamination in the clean room and the locally cleaned region.

As described above, the local cleaning system of this embodiment makes it possible to easily change an arbitrary region of the clean room to a locally cleaned region having a necessary cleanliness level in a short time and isolate the locally cleaned region from the other region of the clean room. Therefore, the maintenance or the like for a fabrication facility can promptly be carried out, resulting in the enhanced operating rate of the semiconductor device fabrication facility. Since the local cleaning system can prevent the fabrication facility from being contaminated during the maintenance and the ambient environment from being contaminated, this can improve yields of semiconductor devices in a semiconductor device fabrication process.

### Embodiment 2

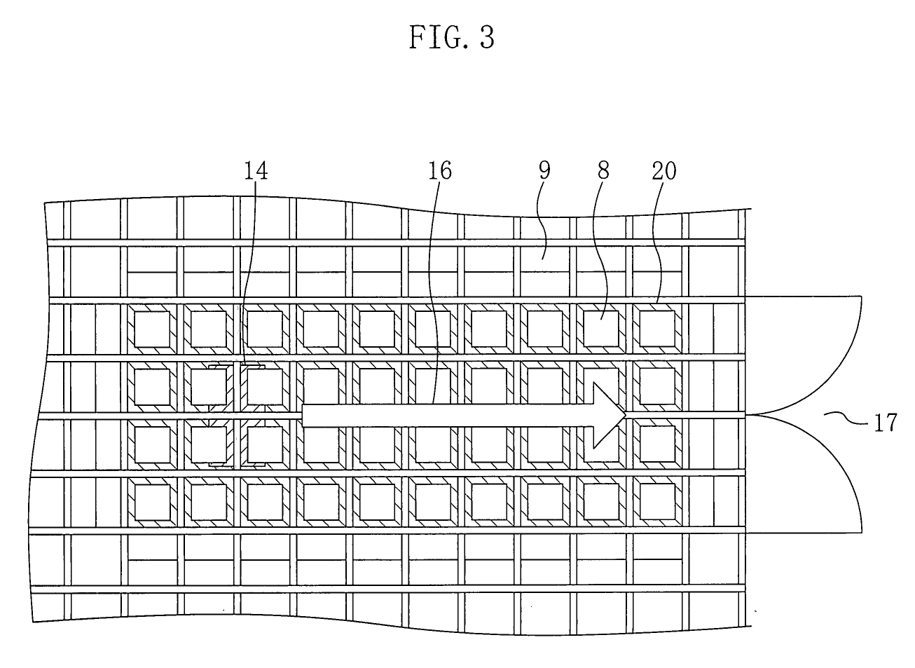

A second embodiment of the present invention will be described hereinafter with reference to the drawing. FIG. 3 shows a plan configuration of a clean room having a local cleaning system of the present invention when a facility is to be carried out of the clean room. In FIG. 3, the same components as those in FIG. 2 are denoted by the same reference numerals, and the description thereof is omitted here.

As shown in FIG. 3, self-traveling fan filter units 8 are successively arranged over a path 16 through which a fabrication facility 14 for semiconductor devices is carried out of the clean room (hereinafter, referred to as “carry-out path 16”) to a carry-in/out port 17. Thus, a region of the clean room covering the vicinity of the carry-in/out port 17 and the carry-out path 16 has a higher cleanliness level than the other region thereof. This can prevent the fabrication facility from being contaminated during transport operations.

Furthermore, self-traveling partition units 9 are placed around a locally cleaned region in which the self-traveling fan filter units 8 are placed, thereby isolating the locally cleaned region from the other region of the clean room. This can prevent contaminants produced during the transport operations from dispersing into the clean room. In addition, the self-traveling partition units 9 placed in the vicinity of the carry-in/out port 17 can prevent contaminants from entering from the outside of the clean room into the clean room.

Although in this embodiment a description was given of the case where a facility is carried out of the clean room, the same effects can be obtained also when a facility is carried into the clean room.

### Embodiment 3

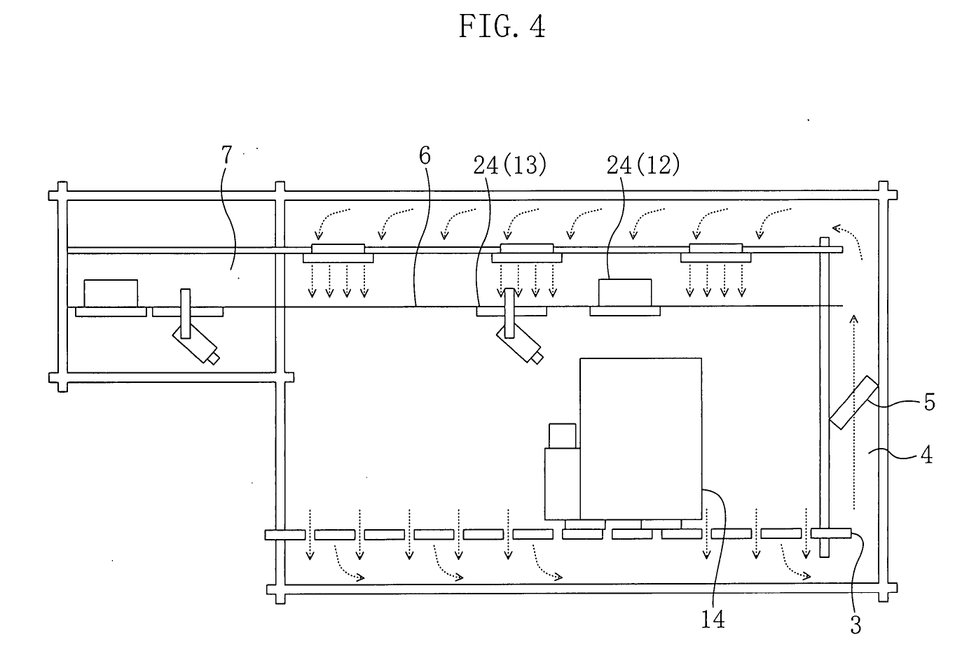

A third embodiment of the present invention will be described hereinafter with reference to the drawing. FIG. 4 shows a cross-sectional structure of a clean room having a clean room monitoring system of the present invention. In FIG. 4, the same components as those in FIG. 1 are denoted by the same reference numerals, and the description thereof is omitted here.

As shown in FIG. 4, self-traveling monitoring units 24 are mounted on transport rails 6 to monitor the state of the clean room. The self-traveling monitoring units 24 are obtained by equipping traveling objects, for example, with a gas detector 12 and a viewing camera apparatus 13. The traveling objects may be equipped with a combination of a plurality of apparatuses.

The self-traveling monitoring units 24 are designed in accordance with the size of each of grid squares or rectangles formed by the transport rails 6 and can arbitrarily be moved along the transport rails 6 in accordance with external instructions. Furthermore, data in the clean room, which are obtained by the self-traveling monitoring units 24, can always be transmitted to the outside by radio communication.

When like the first and second embodiments the self-traveling fan filter units 8, the self-traveling partition units 9 and the self-traveling monitoring units 24 are concurrently used, this makes it possible to form a locally cleaned region 20 in the clean room and monitor the state of the formed locally cleaned region 20 from the outside of the clean room.

According to the clean room monitoring system of this embodiment, the state of an arbitrary region of the clean room can always be monitored from outside by the self-traveling monitoring units 24. Furthermore, since the clean room is monitored from the upper part of the clean room using the transport rails 6, this makes it possible to monitor also a region of the clean room that cannot be reached by human beings, for example, a region thereof located behind the semiconductor device fabrication facility. This can prevent contaminants from being produced due to the movement of human beings.

What is claimed is:

1. A clean room in which a fabrication facility for semiconductor devices is placed, said clean room comprising a plurality of transport rails arranged below a ceiling of the clean room to form a grid.

2. A local cleaning system comprising
a plurality of transport rails arranged below a ceiling of a clean room to form a grid, and
a self-traveling fan filter unit that can be moved along the transport rails,
wherein the self-traveling fan filter unit is moved to a predetermined region of the clean room using the transport rails, thereby forming a locally cleaned region having a higher cleanliness level than a region of the clean room excluding the predetermined region.

3. The local cleaning system of claim 2, wherein
the self-traveling fan filter unit has at least one of a filter for particle removal and a chemical filter.

4. The local cleaning system of claim 2 further comprising
a plurality of self-traveling partition units that can be moved along the transport rails and form a partition for blocking the flow of air,
wherein the self-traveling partition units are placed around the locally cleaned region, thereby blocking the flow of air between the locally cleaned region and the region of the clean room excluding the predetermined region.

5. The local cleaning system of claim 4, wherein
each said self-traveling partition unit is an air curtain unit for blowing air out to form an air curtain.

6. The local cleaning system of claim 4, wherein
each said self-traveling partition unit is a roll curtain unit in which a roll curtain can be contained.

7. The local cleaning system of claim 2, wherein
an area in which the self-traveling fan filter unit and the self-traveling partition units are contained is formed outside the clean room.

8. A method of use of a local cleaning system including a clean room in which a fabrication facility for semiconductor devices is placed, the clean room comprising transport rails arranged below a ceiling of the clean room to form a grid and a self-traveling fan filter unit that can be moved along the transport rails, the self-traveling fan filter unit being moved to a predetermined region of the clean room using the transport rails and thereby forming a locally cleaned region in the predetermined region of the clean room to have a higher cleanliness level than a region thereof excluding the predetermined region,
wherein said method comprises the steps of:
forming a locally cleaned region in a region of the clean room in which the fabrication facility for semiconductor devices is placed; and
performing maintenance of the fabrication facility for semiconductor devices in the locally cleaned region.

9. The method of claim 8 further comprising the step of transferring parts, tools or equipment used in the step of performing maintenance of the facility to the locally cleaned region using the transport rails.

10. A method of use of a local cleaning system including a clean room in which a fabrication facility for semiconductor devices is placed, the clean room comprising transport rails arranged below a ceiling of the clean room to form a grid and a self-traveling fan filter unit that can be moved along the transport rails, the self-traveling fan filter unit being moved to a predetermined region of the clean room using the transport rails and thereby forming a locally cleaned region in the predetermined region of the clean room to have a higher cleanliness level than a region thereof excluding the predetermined region,
wherein said method comprises the steps of:
forming a locally cleaned region in a region of the clean room located in the vicinity of a carry-in/out port and a region thereof serving as a carry-in/out path; and
carrying the fabrication facility for semiconductor devices into and out of the clean room along the carry-in/out path contained in the locally cleaned region.

11. A method of use of a local cleaning system including a clean room in which a fabrication facility for semiconductor devices is placed, the clean room comprising transport rails arranged below a ceiling of the clean room to form a grid and a self-traveling fan filter unit that can be moved along the transport rails, the self-traveling fan filter unit being moved to a predetermined region of the clean room using the transport rails and thereby forming a locally cleaned region in the predetermined region of the clean room to have a higher cleanliness level than a region thereof excluding the predetermined region,
wherein said method comprises the steps of:
forming the locally cleaned region in a region of the clean room in which the semiconductor devices are to be fabricated; and
fabricating the semiconductor devices in the locally cleaned region.

12. A clean room monitoring system comprising:
a plurality of transport rails arranged below a ceiling of a clean room to form a grid;
a self-traveling monitoring unit to which a gas detector or a viewing camera apparatus is mounted and which can be moved along the transport rails; and
a self-traveling-monitoring-unit controller located outside the clean room to move and monitor the self-traveling monitoring unit.
